(19) United States
(12) Patent Application Publication
(10) Pub. No.: US 2006/0138549 A1
(43) Pub. Date: Jun. 29, 2006

(54) High-voltage transistor and fabricating method thereof

(76) Inventor: Kwang Young Ko, Bucheon city (KR)

Correspondence Address: MCKENNA LONG & ALDRIDGE LLP;Song K. Jung, 1900 K Street, N.W., Washington, DC, 20006, US

(21) Appl. No.: 11/314,365

(22) Filed: Dec. 22, 2005

(30) Foreign Application Priority Data
Dec. 29, 2004 (KR) 10-2004-0115646

(51) Int. Cl. H01L 29/94

(52) U.S. Cl. 257/368

(57) ABSTRACT

A high-voltage transistor having a low on-resistance and fabricating method thereof are provided. The high-voltage transistor includes a substrate; a shallow-trench isolation layer provided to an upper part of the substrate to a prescribed depth to define an active area; an extended drain region enclosing the shallow-trench isolation layer; a source region provided to an upper part of the substrate to be spaced apart from the extended drain region by a channel area; a drain region provided beneath the shallow-trench isolation layer within the extended drain region; a gate insulating layer pattern provided on the channel area; and a gate conductive layer pattern provided on the gate insulating layer pattern.

This application claims the benefit of Korean Patent Application No. 10-2004-0115646, filed on Dec. 29, 2004, which is hereby incorporated by reference for all purposes as if fully set forth herein.

### BACKGROUND OF THE INVENTION

1. Field of the Invention

The present invention relates to a semiconductor device, and more particularly, to a high-voltage transistor having a low on-resistance and fabricating method thereof.

2. Discussion of the Related Art

Referring to FIG. 1, illustrating a related art semiconductor device, a high-voltage transistor of about 30V is arranged in a high-voltage transistor area and a low-voltage transistor is arranged in a low-voltage transistor area. A shallow-trench isolation layer 111 is used as a device isolation layer for each of the high and low-voltage transistors.

The high-voltage transistor includes n+ type source/drain regions 141 provided in predetermined upper parts of a p− type substrate 100 to be spaced apart from each other. The drain region 141 is arranged within an n− type extended drain area 103 working as a drift area. The substrate 100 between the n+ type source region 141 and the n− type extended drain area 103 corresponds to a channel area 101. A gate insulating layer pattern 121 and a gate conductive layer pattern 122 are sequentially stacked on the channel area 101. A gate spacer layer 123 is provided on both lateral sides of the gate insulating layer pattern 121 and the gate conductive layer pattern 122. The n+ type source/drain regions 141 are electrically connected to source and drain electrodes S and D, respectively.

The low-voltage transistor includes n+ type source/drain regions 151 provided in predetermined upper parts of the p− type substrate 100 to be spaced apart from each other. The substrate 100 between the n+ type source/drain regions 151 corresponds to a channel area 102. A gate insulating layer pattern 131 and a gate conductive layer pattern 132 are sequentially stacked on the channel area 102. A gate spacer layer 133 is provided on both lateral sides of the gate insulating layer pattern 131 and the gate conductive layer pattern 132. The n+ type source/drain regions 151 are electrically connected to source and drain electrodes S and D, respectively.

A semiconductor device having the above-configured high-voltage transistor employs a shallow-trench isolation layer 111 for the electrical field reduction at an edge of the gate conductive layer pattern 122 and the device isolation in the high-voltage transistor area. Yet, it is difficult for the shallow-trench isolation layer 111 to provide a required internal pressure. Since a current path (shown by arrow) is elongated due to a linear profile of the shallow-trench isolation layer 111, the on-resistance of the corresponding device is raised.

### SUMMARY OF THE INVENTION

Accordingly, the present invention is directed to a high-voltage transistor and fabricating method thereof that substantially obviate one or more problems due to limitations and disadvantages of the related art.

An advantage of the present invention is to provide a high-voltage transistor and fabricating method thereof, by which on-resistance of a device is lowered by shortening a current path.

Additional features and advantages of the invention will be set forth in the description which follows, and in part will be apparent to those from the description or may be learned by practice of the invention. The objectives and other advantages of the invention will be realized and attained by the structure and method particularly pointed out in the written description and claims hereof as well as the appended drawings.

To achieve these and other advantages and in accordance with the purpose of the invention, as embodied and broadly described, there is provided a high-voltage transistor comprising a substrate; a shallow-trench isolation layer provided to an upper part of the substrate to a prescribed depth to define an active area, an extended drain region enclosing the shallow-trench isolation layer; a source region provided to an upper part of the substrate to be spaced apart from the extended drain region by a channel area; a drain region provided beneath the shallow-trench isolation layer within the extended drain region; a gate insulating layer pattern provided on the channel area; and a gate conductive layer pattern provided on the gate insulating layer pattern.

In another aspect of the present invention, there is provided a method of fabricating a high-voltage transistor, the method comprising forming an extended drain region in a high-voltage transistor area of a semiconductor substrate; forming a shallow-trench isolation layer in the high-voltage transistor area and a low-voltage transistor area; forming a gate stack having a gate insulating layer pattern and a gate conductive layer pattern stacked on the gate insulating layer pattern in each of the high and low-voltage transistor areas; removing portions of the shallow-trench isolation layer within the high-voltage transistor area to expose portions of the semiconductor substrate, respectively; and forming a drain region, a source region of the high-voltage transistor area, and source/drain regions of the low-voltage transistor area using the shallow-trench isolation layer as an ion implantation mask layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principles of the invention. In the drawings:

FIG. 1 is a cross-sectional diagram of a semiconductor device having a high-voltage transistor according to a related art; and

FIG. 2 and FIG. 3 are cross-sectional diagrams of a semiconductor device including a high-voltage transistor according to the present invention.

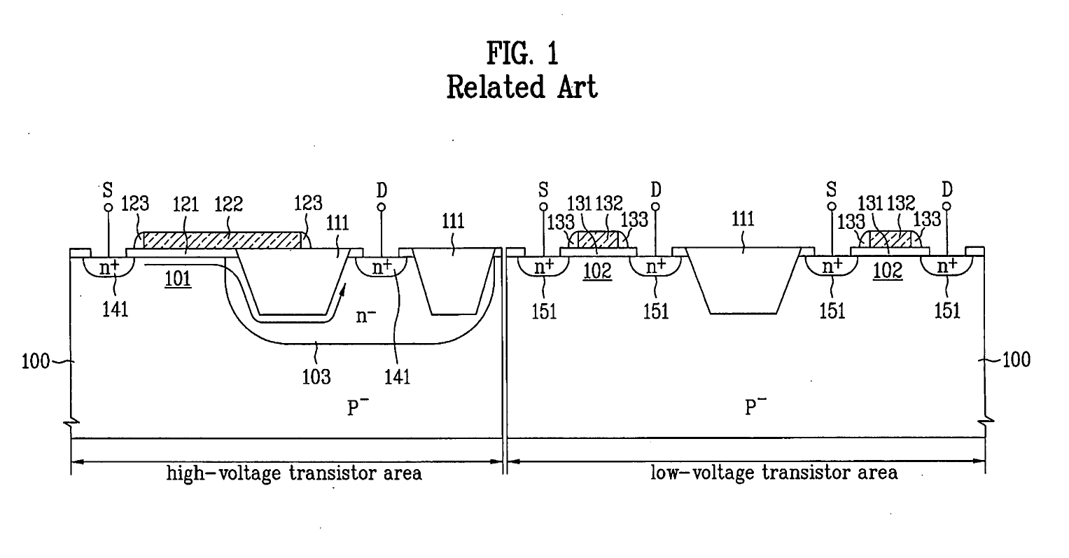

### DETAILED DESCRIPTION OF THE INVENTION

Reference will now be made in detail to embodiments of the present invention, examples of which are illustrated in the accompanying drawings. Wherever possible, like reference designations will be used throughout the drawings to refer to the same or similar parts.

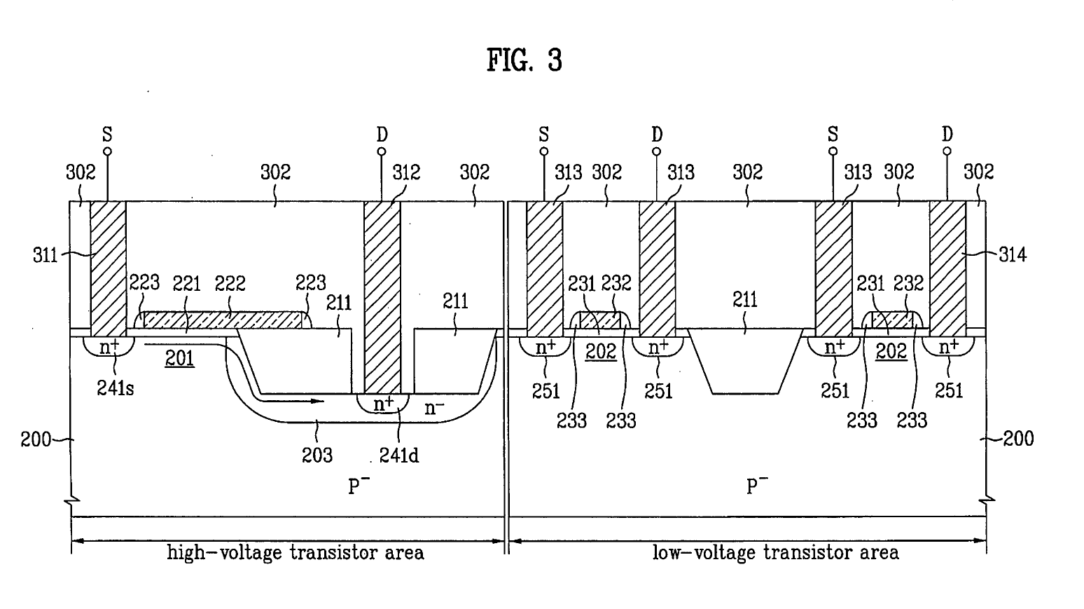

Referring to FIG. 3, illustrating a semiconductor device having a high-voltage transistor according to the present invention, the semiconductor device including includes a high-voltage transistor area and a low-voltage transistor area. A high-voltage transistor according to the present invention is arranged in the high-voltage transistor area and a low-voltage transistor is arranged in the low-voltage transistor area.

The high-voltage transistor, which is arranged in the high-voltage transistor area, includes a shallow-trench isolation layer 211 provided to a predetermined area of a substrate 200. The shallow-trench isolation layer 211 reduces an electric field at an edge of a gate conductive layer pattern 222 and is provided for device isolation. The shallow-trench isolation layer 211 may define an active area of the high-voltage transistor.

The shallow-trench isolation layer 211 is enclosed by an extended drain region 203. The extended drain region 203 is used as a drift region. A pre-metal dielectric layer 302 penetrating the shallow-trench isolation layer 211 is provided to a portion of the shallow-trench isolation layer 211. A drain region 241d is provided beneath the dielectric layer 302 to contact with the pre-metal dielectric layer 302.

A source region 241s is provided in a predetermined upper part of the substrate 200 to be spaced apart from the extended drain region 203 by a channel area 201. A current path from the source region 241s, as indicated by an arrow in the drawing, includes the channel area 201 and the drain region 241d along a lateral side and lower surface of the shallow-trench isolation layer 211 via a surface of the extended drain region 203. As the current path of the present invention is shorter than the related art current path that reaches the drain region beyond the shallow-trench isolation layer, on-resistance is reduced to increase on-current.

A gate insulating layer pattern 221 and a gate conductive layer pattern 222 are sequentially stacked on the channel area 201. A gate spacer layer 223 is provided on lateral sides of the gate insulating and conductive layer patterns 221 and 222.

The pre-metal dielectric layer 302 is provided to an entire surface of the substrate 200 having the above-configured high-voltage transistor. A source contact 311 is provided to penetrate the pre-metal dielectric layer 302 so that the source region 241s can be connected to a source electrode S. A drain contact 312 is provided to penetrate the pre-metal dielectric layer 302 so that the drain region 241d can be connected to a drain electrode D.

The low-voltage transistor provided to the low-voltage transistor area includes source/drain regions 251 provided on predetermined upper parts of the substrate 200, respectively to be spaced apart from each other by a channel area 202. A gate insulating layer pattern 231 and a gate conductive layer pattern 232 are sequentially stacked on the channel area 202. A gate spacer layer 233 is provided on lateral sides of the gate insulating and conductive layer patterns 231 and 232. The source/drain regions 251 are electrically connected to source and drain electrodes S and D by source and drain contacts 313 and 314 penetrating the pre-metal dielectric layer 302, respectively.

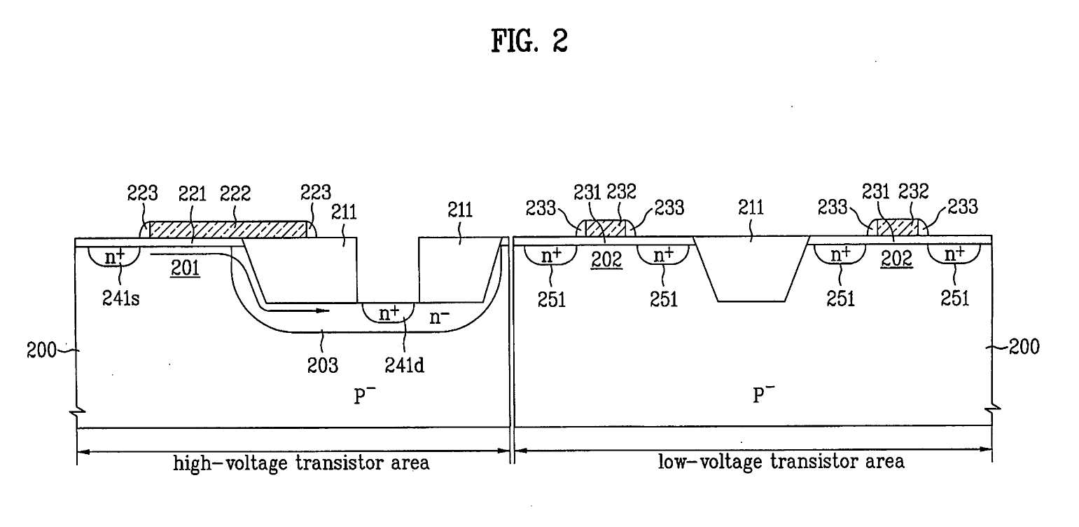

A method of fabricating a high-voltage transistor according to the present invention is explained with reference to FIGS. 2 and 3.

Referring to FIG. 2, a well is formed in a high-voltage transistor area by ion implantation and annealing, after which an extended drain region 203 is formed. A shallow-trench isolation layer 211 is formed in the high-voltage transistor area and a low-voltage transistor area. The shallow-trench isolation layer 211 is formed by conventional techniques. For instance, a hard mask layer pattern is formed on a substrate, a trench is formed on a substrate 200 by etching using the hard mask layer pattern as an etch mask, an oxide liner is formed, the trench is filled with an insulating layer, the shallow-trench isolation layer 211 is completed by planarization, and the hard mask layer pattern is then removed.

After completion of the shallow-trench isolation layers 211 in each of the high and low-voltage transistor areas, ion implantation and annealing are carried out on the low-voltage transistor area to form another well. Gate insulating layer patterns 221 and 231 and gate conductive layer patterns 222 and 232 are sequentially stacked on the high and low-voltage transistor areas to form gate stacks, respectively.

A portion of the shallow-trench isolation layer 211 is partially removed or etched to perforate the shallow-trench isolation layer 211 within the high-voltage transistor area. Hence, a surface of the substrate 200 is exposed via the etched shallow-trench isolation layer 211. A drain region 241d is formed on the substrate 200 exposed via the shallow-trench isolation layer 211 using the shallow-trench isolation layer 211 as an ion implantation mask layer defining a drain region. In performing ion implantation and annealing to form the drain region 241d, a source region 241s of the high-voltage transistor area and source/drain regions 251 of the low-voltage transistor area are simultaneously formed.

Referring to FIG. 3, a nitride liner (not shown) is formed on the substrate to a thickness of about 300˜400 Å, to be used as an etch stop layer in forming contacts. A pre-metal dielectric layer 302 is then formed. By the pre-metal dielectric layer 302, an empty space within the shallow-trench isolation layer 211 is completely filled. The pre-metal dielectric layer 302 is etched using a mask pattern to form contact holes exposing the source and drain regions 241s and 241d of the high-voltage transistor area and the source/drain regions 251 of the low-voltage transistor area, respectively. By filling the contact holes with a metal layer, source and drain contacts 311 and 312 are formed within the high-voltage transistor area and source and drain contacts 313 and 314 are formed within the low-voltage transistor area.

Accordingly, in the high-voltage transistor according to the present invention, since the drain region is provided beneath the shallow-trench isolation layer in contact with a bottom side of the shallow-trench isolation layer, current from the source region to the drain region under the shallow-trench isolation layer can be reduced. Hence, by reducing the on-resistance of the device, the on-current can be increased.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A high-voltage transistor, comprising:
a substrate;
a shallow-trench isolation layer in the shallow trench provided to an upper part of the substrate to a prescribed depth to define an active area;
an extended drain region enclosing the shallow-trench isolation layer;
a source region provided to an upper part of the substrate to be spaced apart from the extended drain region by a channel area;
a drain region at a level below the shallow-trench isolation layer within the extended drain region;
a gate insulating layer pattern provided on the channel area; and
a gate conductive layer pattern provided on the gate insulating layer pattern.

2. The high-voltage transistor of claim 1, further comprising an insulating layer penetrating the shallow-trench isolation layer to contact with the drain region.

3. The high-voltage transistor of claim 2, wherein the drain region is electrically connected by a contact plug through the insulating layer to an electrode.

4. A method of fabricating a high-voltage transistor, comprising:
forming an extended drain region in a high-voltage transistor area of a semiconductor substrate;
forming a shallow-trench isolation layer;
forming a gate stack having a gate insulating layer pattern and a gate conductive layer pattern stacked on the gate insulating layer pattern;
removing portions of the shallow-trench isolation layer to expose portions of the semiconductor substrate; and
forming a drain region and a source region such that the drain region is formed in the extended drain region at a level below the shallow trench isolation layer.

5. The method of claim 4, further comprising:
forming a pre-metal dielectric layer over the semiconductor substrate;
forming contact holes exposing the source and drain regions by selectively removing portions of the pre-metal dielectric layer; and
forming source and drain contacts by filling the contact holes with a metal layer.
